(19) United States
(12) Patent Application Publication
(10) Pub. No.: US 2026/0101757 A1
(43) Pub. Date: Apr. 9, 2026

(54) PACKAGE STRUCTURE

(71) Applicant: Advanced Semiconductor Engineering, Inc., Kaohsiung (TW)

(72) Inventors: Meng-Jen WANG, Kaohsiung (TW); Shao-Chang LEE, Kaohsiung (TW); Cheng-Yu TSAI, Kaohsiung (TW); Shih-Wei TIEN, Kaohsiung (TW); Jyun-Jhih YANG, Kaohsiung (TW); You-Chi WANG, Kaohsiung (TW); Dian-Yong LI, Kaohsiung (TW)

(73) Assignee: Advanced Semiconductor Engineering, Inc., Kaohsiung (TW)

(21) Appl. No.: 18/906,112

(22) Filed: Oct. 3, 2024

(51) Int. Cl. H01L 23/552; H01L 23/00; H01L 23/31; H01L 23/498; H01L 25/16

(52) U.S. Cl. CPC H10W 42/20; H10W 74/117; H10W 74/121; H10W 90/00; H10W 70/65; H10W 74/10; H10W 90/724

(57) ABSTRACT

A package structure is provided. The package structure includes a substrate, a first electronic component, a second electronic component, an encapsulant, and a third electronic component. The first electronic component and the second electronic component are disposed over the substrate. The encapsulant encapsulates first electronic component and the second electronic component. The third electronic component is exposed by the encapsulant. A wafer node of the third electronic component is less than a wafer node of the first electronic component.

### BACKGROUND

### 1. Technical Field

The present disclosure relates generally to a package structure.

### 2. Description of the Related Art

Typically, in high-density semiconductor packaging, multiple dies or modules can be arranged side-by-side or can be stacked vertically within a package to form a system-in-package (SiP). However, mutual electromagnetic interference occurs between the dies or modules in the package, and external electromagnetic signals also interfere with the operation of these dies or modules, which may result in damage of the dies or modules and malfunction of the package incorporating these dies or modules. Hence, an improved package structure having a shielding structure is desired to provide a more effective electromagnetic shielding capability.

However, when multiple modules are encapsulated separately, the shielding structure may be required to be formed separately accordingly. Alternatively, a shielding material may be formed on selected areas each corresponding to one of the modules with a keep-out-zone (KOZ) left out, which may result in issues of incomplete formation of the shielding structure or even low yields.

### SUMMARY

In one or more arrangements, a package structure includes a substrate, a first electronic component, a second electronic component, an encapsulant, and a third electronic component. The first electronic component and the second electronic component are disposed over the substrate. The encapsulant encapsulates first electronic component and the second electronic component. The third electronic component is exposed by the encapsulant. A wafer node of the third electronic component is less than a wafer node of the first electronic component.

In one or more arrangements, a package structure includes a substrate, an encapsulant, an electronic component, a connection element, and a dielectric layer. The substrate includes a ground element at an upper surface of the substrate. The encapsulant is disposed on the upper surface of the substrate and exposes the ground element. The electronic component is disposed on the upper surface of the substrate exposed by the encapsulant. The ground element is positioned between the encapsulant and the electronic component. The connection element is disposed in a gap between the electronic component and the substrate and is configured to electrically connect the electronic component to the substrate. The dielectric layer encapsulates the connection element and is spaced apart from the ground element. The gap is not entirely filled by the dielectric layer.

In one or more arrangements, a package structure includes a substrate, a plurality of first electronic components, a first encapsulant, a plurality of second electronic components, and a first shielding layer. The substrate supports the first electronic components. The first encapsulant encapsulates the first electronic components. The second electronic components are over the substrate and are exposed by the first encapsulant. The first shielding layer is adhered to an outer lateral surface of the first encapsulant and is configured to accommodate the second electronic components.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1A is a cross-section of a package structure in accordance with some arrangements of the present disclosure.

FIG. 1B is a top view of a package structure in accordance with some arrangements of the present disclosure.

FIG. 2A is a cross-section of a portion of a package structure in accordance with some arrangements of the present disclosure.

FIG. 2B is a cross-section of a portion of a package structure in accordance with some arrangements of the present disclosure.

FIG. 2C is a cross-section of a portion of a package structure in accordance with some arrangements of the present disclosure.

FIG. 2D is a cross-section of a portion of a package structure in accordance with some arrangements of the present disclosure.

FIG. 2E is a cross-section of a portion of a package structure in accordance with some arrangements of the present disclosure.

FIG. 3A is a cross-section of a package structure in accordance with some arrangements of the present disclosure.

FIG. 3B is a cross-section of a package structure in accordance with some arrangements of the present disclosure.

FIG. 4 is a top view of a package structure in accordance with some arrangements of the present disclosure.

FIG. 5A to FIG. 5I illustrate various stages of an exemplary method of forming a package structure in accordance with some arrangements of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

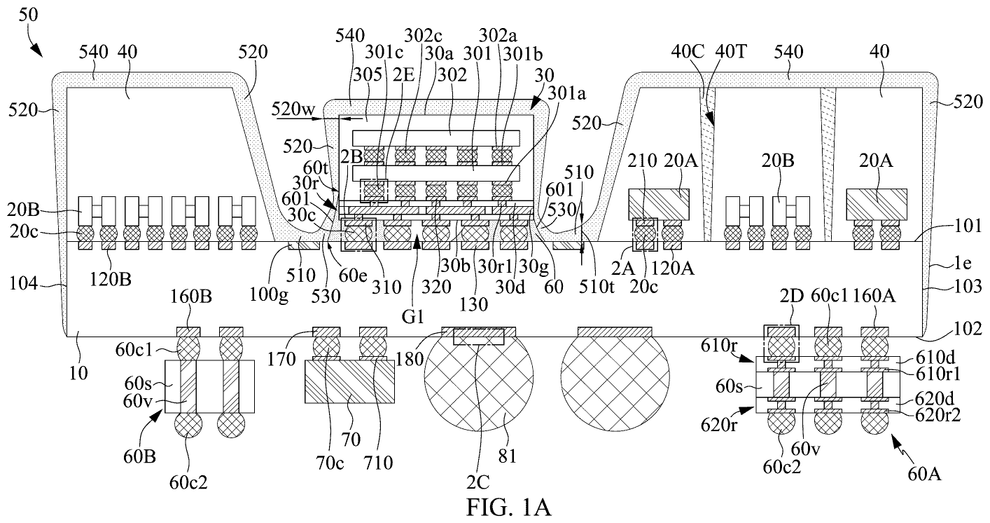

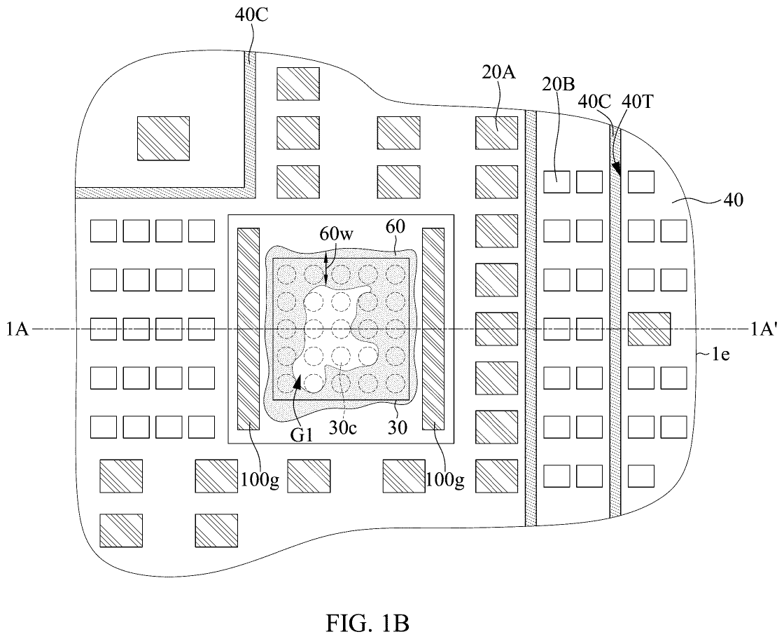

FIG. 1A is a cross-section of a package structure 1 in accordance with some arrangements of the present disclosure. FIG. 1B is a top view of a package structure 1 in accordance with some arrangements of the present disclosure. In some arrangements, FIG. 1A is a cross-section along a line 1A-1A′ in FIG. 1B. The package structure 1 may include a substrate 10, electronic components 20A, 20B, 30, and 70, an encapsulant 40, a shielding element 50, a barrier 60, connectors 60A and 60B, and electrical contacts 81. The package structure 1 may be or include a multiple system shielding module (MSSM).

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, such as a plurality of conductive traces and/or a plurality of conductive vias. In some arrangements, the substrate 10 includes a ceramic material, a metal plate, an organic substrate, or a leadframe. In some arrangements, the substrate 10 may include a two-layer substrate which includes a core layer and a conductive material and/or structure disposed on an upper surface and a bottom surface of the substrate 10. The conductive material and/or structure may include a plurality of conductive traces. The substrate 10 may include a surface 101, a surface 102 opposite to the surface 101, and lateral surfaces 103 and 104 extending between the surface 101 and the surface 102. In some arrangements, the substrate 10 includes conductive pads 120A, 120B, and 130 exposed from the surface 101. In some arrangements, the substrate 10 includes conductive pads 160A, 160B, 170, and 180 exposed from the surface 102. In some arrangements, the substrate 10 includes a ground element 100g exposed from the surface 101.

The electronic components 20A and 20B may be disposed over the substrate 10. In some arrangements, the electronic components 20A and 20B include surface mount devices (SMDs). Each of the electronic components 20A and 20B may be a chip or a die including a semiconductor substrate, one or more integrated circuit devices and one or more overlying interconnection structures therein. The integrated circuit devices may include active devices such as transistors and/or passive devices such resistors, capacitors, inductors, or a combination thereof. In some arrangements, the electronic component 20A includes an active device (e.g., a PMIC, an ASIC, or the like), and the electronic component 20B includes a passive device (e.g., a capacitor or the like).

The electronic component 30 may be disposed over the substrate 10. In some arrangements, a wafer node of the electronic component 30 is less than a wafer node of the electronic component 20A. In some arrangements, a wafer node of the electronic component 30 is less than a wafer node of the electronic component 20B. In some arrangements, a gate length of transistors of the electronic component 30 is less than a gate length of transistors of the electronic component 20A. In some arrangements, a gate length of transistors of the electronic component 30 is less than a gate length of transistors of the electronic component 20B. In some arrangements, the manufacturing cost for the electronic component 30 is higher than the manufacturing cost for the electronic components 20A and 20B. In some arrangements, the electronic component 30 has a top surface 30a (also referred to as an upper surface) and a bottom surface 30b (also referred to as a lower surface) facing the substrate 10. In some arrangements, the bottom surface 30b is spaced apart from the surface 101 of the substrate 10 by a gap G1 (or a space). The gap G1 may be an air gap. The gap G1 (or the space) may be defined by the barrier 60.

In some arrangements, the electronic component 30 includes electronic devices 301 and 302, a redistribution layer (RDL) 30r, and an encapsulation layer 305 encapsulating the electronic devices 301 and 302. In some embodiments, a wafer node of at least one of the electronic devices 301 and 302 is less than a wafer node of the electronic component 20A. In some embodiments, a gate length of at least one of the electronic devices 301 and 302 is less than a gate length of one of the electronic components 20A and 20B. The RDL 30r may be between the electronic device 301 and the substrate 10. In some arrangements, the RDL 30r includes conductive layers 30r1 and dielectric layers 30d. The conductive layers 30r1 may include conductive traces and conductive vias. In some arrangements, the RDL 30r further includes a ground element 30g exposed by a lateral surface of the RDL 30r. In some arrangements, the electronic device 301 is electrically connected to the RDL 30r through conductive pads 320, connection elements 301c, and conductive pads 301a. In some arrangements, the electronic device 302 is electrically connected to the electronic device 301 through conductive pads 301b, connection elements 302c, and conductive pads 302a. The connection elements 301c and 302c may include solder elements. The electronic devices 301 and 302 may independently be or include system-on-chip (SoC), package-on-package (PoP), MEMS, or the like. The electronic component 30 may be or include a system-in package (SiP).

In some arrangements, connection elements 20c are between the substrate 10 and the electronic components 20A and 20B. In some arrangements, the electronic components 20A are electrically connected to conductive pads 120A of the substrate 10 through the connection elements 20c and conductive pads 210. In some arrangements, the electronic components 20B are electrically connected to conductive pads 120B of the substrate 10 through the connection elements 20c. In some arrangements, connection elements 30c are between the substrate 10 and the electronic component 30. In some arrangements, the electronic component 30 is electrically connected to conductive pads 130 of the substrate 10 through the connection elements 30c and conductive pads 310. The connection elements 20c and 30c may include solder elements.

The barrier 60 (also referred to as “barrier structure” or “barrier element”) may be disposed over the substrate 10 and adjacent to the electronic component 30. In some arrangements, the barrier 60 is configured to prevent the shielding element 50 from extending toward the gap G1 between the electronic component 30 and the substrate 10 to electrically connect to the connection elements 30c during a sputtering operation. In some arrangements, the barrier 60 may serve as a spacer or an elevation element that is configured to reduce the range or the size of the portion 520 of shielding element 50 that tapers toward the substrate 10, such that cracking or breaking of the shielding element 50 can be prevented. In some arrangements, the barrier 60 has a surface 601 facing upwards (or away from the substrate 10) and configured to provide a deposition surface for the shielding element 50. In some arrangements, the barrier 60 includes at least a portion overlapping the electronic component (30) in a direction substantially parallel to the surface 101 of the substrate 10, and the portion is configured to support the shielding element 50. The surface 601 may be non-parallel to or inclined with respect to the surface 101 of the substrate 10. The barrier 60 may be or include a dielectric layer. In some arrangements, the ground element 100g is exposed by the encapsulant 40 and the barrier 60. In some arrangements, a top end 60t of the barrier 60 is closer to the bottom surface 30b than to the top surface 30a of the electronic component 30. In some arrangements, a lateral edge 60e of the barrier 60 is closer to the electronic component 30 than to the encapsulant 40. In some arrangements, the barrier 60 contacts a portion of the RDL 30r. In some arrangements, the barrier 60 is configured to increase a bonding strength between the electronic component 30 and the substrate 10. The barrier 60 may be or include an insulating material or a dielectric material. In some arrangement, the barrier 60 is or includes an underfill. The underfill may include an epoxy resin having fillers dispersed therein, a molding compound (e.g., an epoxy molding compound or other molding compound), polyimide (PI), a phenolic compound or material, a polymer material with silicone dispersed therein, or a combination thereof.

In some arrangements, the barrier 60 is between the connection elements 30c and the shielding element 50. In some arrangements, the barrier 60 contacts at least one of the connection elements 30c. In some arrangements, the barrier 60 is free from contacting at least one of the connection elements 30c in the gap G1. In some cases where the connection elements 30c are exposed without a barrier disposed around, and the shielding element 50 is formed by a selective sputtering operation, i.e., the shielding element is sputtered on selected regions over the encapsulant 40. In such case, the shielding element 50 may extend to contact the connection element 30c when no barrier is disposed between the connection elements 30c and the shielding element 50. In contrast, according to some arrangements of the present disclosure, with the design of the barrier 60 disposed around the connection elements 30c, the barrier 60 can prevent the shielding element 50 from contacting the connection elements 30c and thus prevent the electronic component 30 from being undesirably connected to ground through the connection element 30c that contacts the shielding element 50. Therefore, the yield can be improved.

In some arrangements, the barrier 60 is spaced apart from the ground element 100g. In some arrangements, the barrier 60 is protruded beyond the lateral surface of the electronic component 30 by a relatively small distance. In some cases where a shielding material is sputtered all over the entire region covering the substrate 10, a mask may be disposed to cover the electronic component 30 from being sputtered with the shielding material. Sidewalls of the mask may be relatively thick and thus cover the ground element 100g, the shielding material may leak into the space between the electronic component 30 and the substrate 10 through a gap between the mask and the substrate 10, and the mask may shift and potentially collide with the electronic component 30 to cause damages to the electronic component 30. In contrast, according to some arrangements of the present disclosure, with the design of the barrier 60 disposed around the connection elements 30c, the area over the surface 101 of the substrate 10 covered by the barrier 60 is relatively small, and thus the ground element 100g can be entirely exposed to contact the shielding element 50. Therefore, the yield can be improved. In some arrangements, the barrier 60 is configured to space the shielding element 50 apart from the connection elements 30c instead of covering the connection elements 30c, thus a gap G1 may be formed within the barrier 60 and exposing the connection elements 30c. With the above design, the amount of the barrier 60 can be relatively small, and thus the KOZ can be reduced accordingly.

The encapsulant 40 may be disposed over the surface 101 of the substrate 10. In some arrangements, the encapsulant 40 encapsulates the electronic components 20A and 20B. In some arrangements, the electronic component 30 is exposed by the encapsulant 40. In some arrangements, the encapsulant 40 include trenches 40T penetrating the encapsulant 40. In some arrangements, portions of the surface 101 are exposed to the trenches 40T. In some arrangements, conductive materials may be filled in the trenches 40T to form shielding elements 40C. The shielding elements 40C may be referred to as compartment shielding. The shielding elements 40C may provide electromagnetic interference (EMI) shielding between some of the electronic components 20A and 20B. The shielding element 40C can prevent EMI emissions from the electronic components 20A and/or 20B from one side of the shielding element 40C to the electronic components 20A and/or 20B at an opposite side of the shielding element 40C. The encapsulant 40 may include an epoxy resin having fillers dispersed therein, a molding compound (e.g., an epoxy molding compound or other molding compound), PI, a phenolic compound or material, a polymer material with silicone dispersed therein, or a combination thereof. The shielding element 40C may be or include a conductive paste, a conductive glue, or a conductive film, e.g., for example, aluminum (Al), copper (Cu), chromium (Cr), tin (Sn), gold (Au), silver (Ag), nickel (Ni), a mixture, an alloy, or other combination thereof.

The encapsulant 40 may be referred to as a selective mold. The electronic components 20A and 20B encapsulated by the encapsulant 40 may be referred to as a system-in package (SiP).

The shielding element 50 may be over the electronic components 20A, 20B, and 30. In some arrangements, the shielding element 50 covers the electronic components 20A, 20B, and 30. In some arrangements, the shielding element 50 contacts the electronic component 30, the encapsulant 40, the ground element 100g, the surface 101 of the substrate 10, and the lateral surfaces 103 and 104 of the substrate 10. In some arrangements, the shielding element 50 is disposed along an outer lateral surface of the encapsulant 40 and an outer lateral surface of the electronic component 30. In some arrangements, the shielding element 50 is adhered to an outer lateral surface of the encapsulant 40 and configured to accommodate the electronic devices 301 and 302 of the electronic component 30. In some arrangements, the shielding element 50 is free from contacting the connection elements 30c. In some arrangements, the shielding element 50 is free from extending into a gap G1 between the electronic component 30 and the substrate 10 in a direction substantially perpendicular to the surface 101 of the substrate 10. In some arrangements, the ground element 100g is exposed by the barrier 60 and contacting the shielding element 50. In some arrangements, the barrier 60 is between the connection elements 30c and the shielding element 50. In some arrangements, the barrier 60 is configured to space the shielding element 50 apart from the connection element 30c. In some arrangements, the ground element 30g is exposed by the barrier 60 and contacting the shielding element 50. In some arrangements, the barrier 60 is configured to reduce an extension of the shielding element 50 toward the gap G1 between the electronic component 30 and the substrate 10. The shielding element 50 may be or include a conductive film, e.g., for example, Al, Cu, Cr, Sn, Au, Ag, Ni, stainless steel, a mixture, an alloy, or other combination thereof. The shielding element 50 may include multiple conductive layers

In some arrangements, the shielding element 50 includes portions 510, 520, 530, and 540. In some arrangements, the portions 510, 520, 530, and 540 are formed integrally and conformally over the substrate 10, the electronic component 30, and the encapsulant 40. In some arrangements, the portion 510 extends between the encapsulant 40 and the electronic component 30. In some arrangements, the portion 510 has a thickness 510t decreasing toward the electronic component 30. In some arrangements, the portion 510 has a thickness 510t decreasing from the encapsulant 40 toward the barrier 60. In some arrangements, the portion 510 contacts the ground element 100g.

In some arrangements, the portions 520 extend along sidewalls of the electronic component 30. In some arrangements, the portion 520 contacts the encapsulant layer 305. In some arrangements, the portions 520 extend along sidewalls and slopes of the encapsulant 40. In some arrangements, the portion 520 contacts the encapsulant 40. In some arrangements, the portion 520 tapers toward the substrate 10. In some arrangements, the portion 520 has a width 520w decreasing toward the substrate 10. In some arrangements, the portion 520 further extends over the lateral surfaces 103 and 104 of the substrate 10. In some arrangements, in addition to vertical walls, the encapsulant 40 provides slopes for the portion 520 to be formed thereon, such that the step coverage of the shielding element 50 can be improved, and the uniformity of the shielding element 50 over the entire package structure 1 is improved as well.

In some arrangements, the portions 530 extend between the substrate 10 and the portions 520. In some arrangements, the portion 530 tapers toward the portion 520. In some arrangements, the portion 530 connects the portion 510 to the portion 520.

In some arrangements, the portions 540 extend between the portions 520 and over the electronic component 30 and the encapsulant 40. In some arrangements, the portion 540 has a substantially uniform thickness.

The connectors 60A and 60B may be connected to the surface 102 of the substrate 10. In some arrangements, the connectors 60A and 60B may include interposers. In some arrangements, the connector 60A includes a base layer 60s (or a core layer), RDLs 610r and 620r on opposite surfaces of the base layer 60s, and conductive vias 60v electrically connecting the RDL 610r to the RDL 620r. The base layer 60s may include a dielectric core layer. In some arrangements, the RDL 610r includes a dielectric structure 610d and conductive layers 610r1 in the dielectric structure 610d. The conductive layers 610r1 may include conductive traces and conductive vias. The dielectric structure 610d may include multiple dielectric layers. The connector 60A may be electrically connected to conductive pads 160A of the substrate 10 through connection elements 60c1. Connection elements 60c2 may be disposed on and electrically connected to the RDL 620r. In some arrangements, the connector 60B includes a base layer 60s and conductive vias 60v penetrating the base layer 60s. The connector 60B may be electrically connected to conductive pads 160B of the substrate through connection elements 60c1. Connection elements 60c2 may be disposed on and electrically connected to the conductive vias 60v of the connector 60B. The base layer 60s may be or include a silicon layer, and the conductive vias 60v may be or include through silicon vias.

The electronic component 70 may be connected to the surface 102 of the substrate 10. In some arrangements, the electronic component 70 is electrically connected to conductive pads 170 of the substrate through connection elements 70c. The electronic component 70 may be or include a sensor, e.g., IMU.

The electrical contacts 81 may be connected to the surface 102 of the substrate 10. In some arrangements, the electrical contacts 81 are electrically connected to conductive pads 180 of the substrate 10. In some arrangements, the electrical contacts 15 include controlled collapse chip connection (C4) bumps, a ball grid array (BGA), or a land grid array (LGA).

Referring to FIG. 1B, in some arrangements, the barrier 60 has a non-uniform width 60w from a top view perspective. In some arrangements, the barrier 60 surrounds the connection elements 30c. In some arrangements, the gap G1 is surround and enclosed by the barrier 60. In some arrangements, the gap G1 (or the space) is not entirely filled by the barrier 60. In some arrangements, the ground elements 100g extend at opposite sides of the barrier 60. In some arrangements, the package structure 1 has a peripheral edge 1e with an irregular shape from a top view perspective.

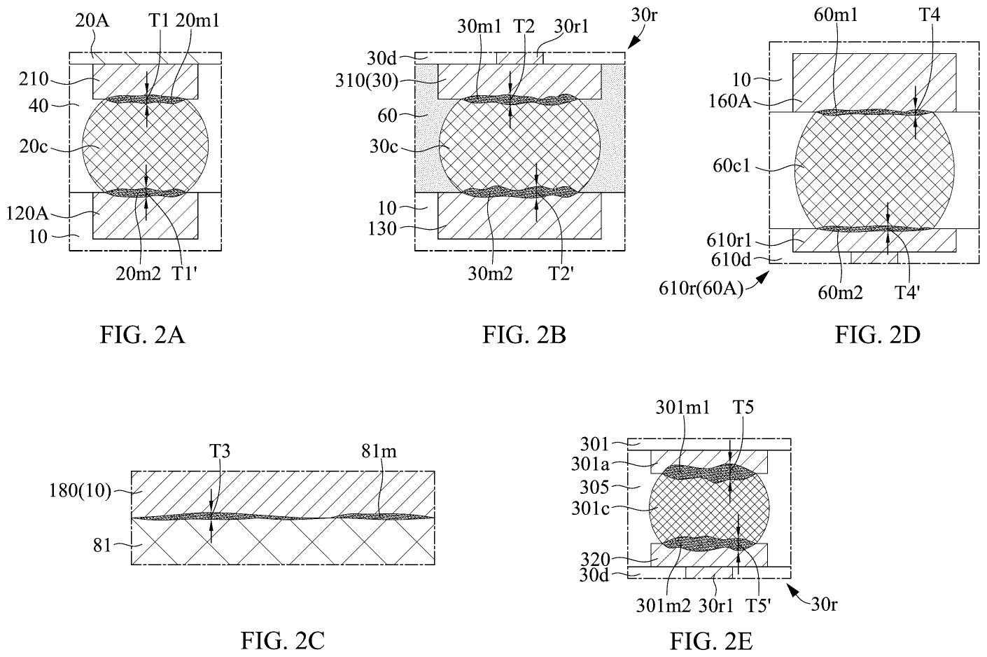

FIG. 2A is a cross-section of a portion of a package structure in accordance with some arrangements of the present disclosure. FIG. 2B is a cross-section of a portion of a package structure in accordance with some arrangements of the present disclosure. In some arrangements, FIG. 2A is a cross-section of a portion 2A in FIG. 1A, and FIG. 2B is a cross-section of a portion 2B in FIG. 1A.

In some arrangements, an intermetallic compound (IMC) layer 20m1 is formed between the electronic component 20A (e.g., the conductive pad 210) and the connection element 20c, and an IMC layer 20m2 is formed between the connection element 20c and the substrate 10 (e.g., the conductive pad 120A). In some arrangements, the IMC layer 20m1 is formed from metals from the conductive pad 210 and the connection element 20c. In some arrangements, the IMC layer 20m2 is formed from metals from the conductive pad 120A and the connection element 20c. In some arrangements, the IMC layer 20m1 has a thickness T1, and the IMC layer 20m2 has a thickness T1′ substantially the same as the thickness T1.

In some arrangements, an IMC layer 30m1 is formed between the electronic component 30 (e.g., the conductive pad 310) and the connection element 30c, and an IMC layer 30m2 is formed between the connection element 30c and the substrate 10 (e.g., the conductive pad 130). In some arrangements, the IMC layer 30m1 is formed from metals from the conductive pad 310 and the connection element 30c. In some arrangements, the IMC layer 30m2 is formed from metals from the conductive pad 130 and the connection element 30c. In some arrangements, the IMC layer 30m1 has a thickness T2, and the IMC layer 30m2 has a thickness T2′ substantially the same as the thickness T2. In some arrangements, the thickness T1 is substantially the same as the thickness T2.

FIG. 2C is a cross-section of a portion of a package structure in accordance with some arrangements of the present disclosure. FIG. 2D is a cross-section of a portion of a package structure in accordance with some arrangements of the present disclosure. In some arrangements, FIG. 2C is a cross-section of a portion 2C in FIG. 1A, and FIG. 2D is a cross-section of a portion 2D in FIG. 1A.

In some arrangements, an IMC layer 81m is formed between the electrical contact 81 and the substrate 10 (e.g., the conductive pad 180). In some arrangements, the IMC layer 81m is formed from metals from the conductive pad 180 and the electrical contact 81. In some arrangements, the IMC layer 81m has a thickness T3 less than the thickness T1 and the thickness T2.

In some arrangements, an IMC layer 60m1 is formed between the substrate 10 (e.g., the conductive pad 160A) and the connection element 60c1, and an IMC layer 60m2 is formed between the connection element 60c1 and the connector 60A (e.g., the conductive pad 120A). In some arrangements, the IMC layer 60m1 is formed from metals from the conductive pad 160A and the connection element 60c1. In some arrangements, the IMC layer 60m2 is formed from metals from the conductive layer 610r1 and the connection element 60c1. In some arrangements, the IMC layer 60m1 has a thickness T4, and the IMC layer 60m2 has a thickness T4′ substantially the same as the thickness T4. In some arrangements, the thickness T3 is substantially the same as the thickness T4.

FIG. 2E is a cross-section of a portion of a package structure in accordance with some arrangements of the present disclosure. In some arrangements, FIG. 2E is a cross-section of a portion 2E in FIG. 1A.

In some arrangements, an IMC layer 301 m1 is formed between the conductive pad 301a and the connection element 301c, and an IMC layer 301m2 is formed between the connection element 301c and the conductive pad 320. In some arrangements, the IMC layer 301 m1 is formed from metals from the conductive pad 310a and the connection element 301c. In some arrangements, the IMC layer 301m2 is formed from metals from the conductive pad 320 and the connection element 60c1. In some arrangements, the IMC layer 301m1 has a thickness T5, and the IMC layer 301m2 has a thickness T5′ substantially the same as the thickness T5. In some arrangements, the thickness T5 is greater than the thicknesses T1, T2, T3, and T4.

In some arrangements, in the process of forming the package structure 1, the electronic device 301 is connected to the RDL 30r through the connection elements 301c by a reflow operation. The IMC layers 301m1 and 301m2 may be formed by the reflow operation. In some arrangements, the electronic components 20A, 20B, and 30 are connected to the substrate through the connection elements 20c and 30c by another reflow operation. The IMC layers 20m1, 20m2, 30m1, and 30m2 may be formed by the reflow operation, which also thickens the IMC layers 30 m1 and 301m2 that have been formed. Next, in some arrangements, the connector 60A is connected to the substrate 10 through the connection elements 60c1 by an additional reflow operation, and the electrical contacts 81 are connected to the substrate 10 by the same additional reflow operation. The additional reflow operation thickens the IMC layers 20m1, 20m2, 30m1, and 30m2 and further thickens the IMC layers 301m1 and 301m2.

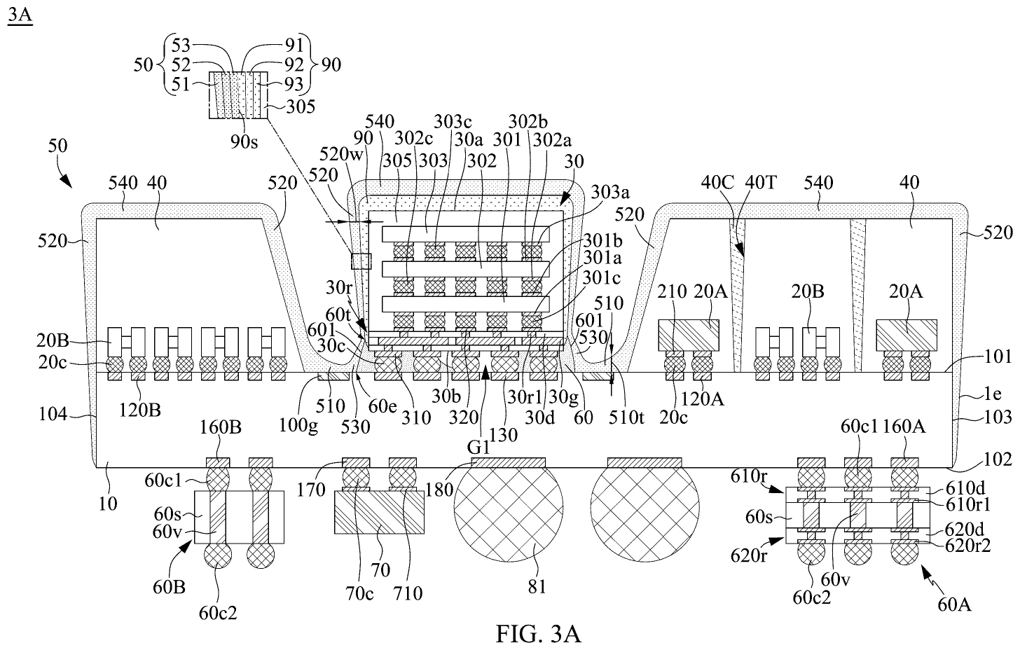

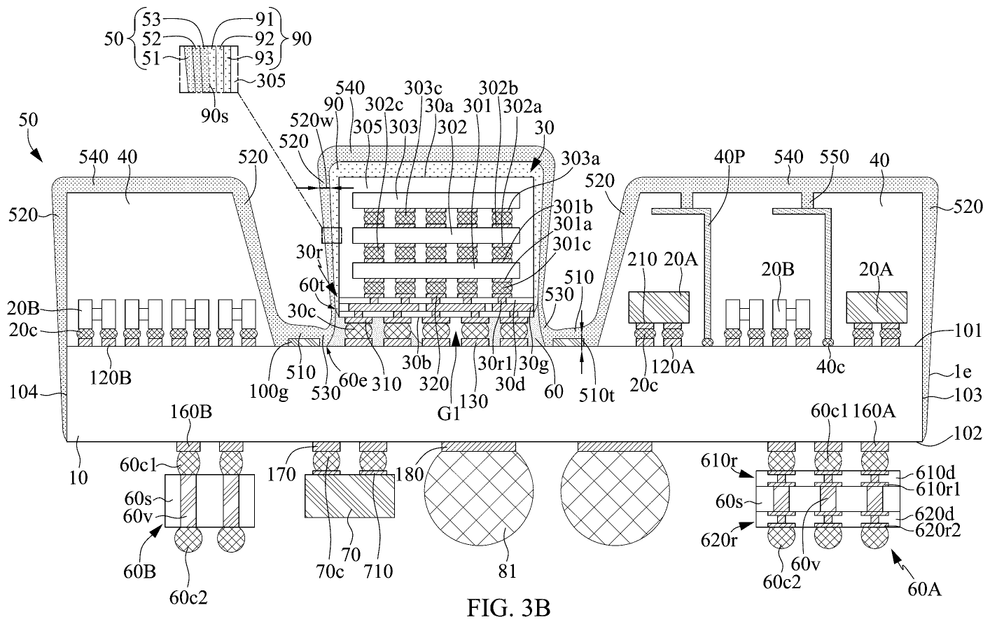

FIG. 3A is a cross-section of a package structure 3A in accordance with some arrangements of the present disclosure. The package structure 3A is similar to the package structure 1 in FIG. 1A and FIG. 1B, and the differences therebetween are described as follows.

In some arrangements, the electronic component 30 further includes a shielding element 90 covering the encapsulant layer 305. In some arrangements, the shielding element 90 is between the electronic component 30 and the shielding element 50. In some arrangements, the shielding element 50 and the shielding element 90 overlap vertically and horizontally. In some arrangements, the shielding element 50 covers and contacts the shielding element 90. In some arrangements, the shielding element 50 includes shielding layers 51, 52, and 53, and the shielding element 90 includes shielding layers 91, 92, and 93. In some arrangements, the shielding layers 52 and 92 include Cu layers, and the shielding layers 51, 53, 91, and 93 include stainless steel layers. In some arrangements, an interface 90s between the shielding elements 50 and 90 may not be observable.

In some arrangements, the electronic component 30 includes electronic devices 301, 302, and 303, a redistribution layer (RDL) 30r, and an encapsulation layer 305 encapsulating the electronic devices 301, 302, and 303. In some arrangements, the electronic device 301 is electrically connected to the RDL 30r through conductive pads 320, connection elements 301c, and conductive pads 301a. In some arrangements, the electronic device 302 is electrically connected to the electronic device 301 through conductive pads 301b, connection elements 302c, and conductive pads 302a. In some arrangements, the electronic device 303 is electrically connected to the electronic device 302 through conductive pads 302b, connection elements 303c, and conductive pads 303a. The connection elements 301c, 302c, and 303c may include solder elements. The electronic devices 301, 302, and 303 may independently be or include system-on-chip (SoC), package-on-package (PoP), MEMS, or the like.

The shielding element 90 covers a portion of the RDL 30r. In some arrangements, the barrier 60 is partially between the shielding element 50 and the shielding element 90. In some arrangements, a portion of the encapsulant 40 extends between the shielding element 50 and the shielding element 90. In some arrangements, the RDL 30r, the shielding element 50, and the shielding element 90 overlap in a direction substantially parallel to the surface 101 of the substrate 10. In some arrangements, the RDL 30r, the shielding element 50, the barrier 60, and the shielding element 90 overlap in a direction substantially parallel to the surface 101 of the substrate 10. In some arrangements, the barrier 60 may be or include a non-conductive film (NCF). In some arrangements, the NCF served as the barrier 60 may have a convex curved surface 601.

FIG. 3B is a cross-section of a package structure 3B in accordance with some arrangements of the present disclosure. The package structure 3B is similar to the package structure 3A in FIG. 3A, and the differences therebetween are described as follows.

In some arrangements, the package structure 3B further includes one or more metal plates 40P and one or more connection elements 40c connecting the metal plates 40P to the substrate 10. In some arrangements, the metal plates 40P may serve as shieling elements providing shielding functions similar to that provided by the shielding elements 40C. The metal plates 40P may be referred to as compartment shielding. The shielding element 50 may include a portion extending into the encapsulant 40 and contacts the metal plate 40P.

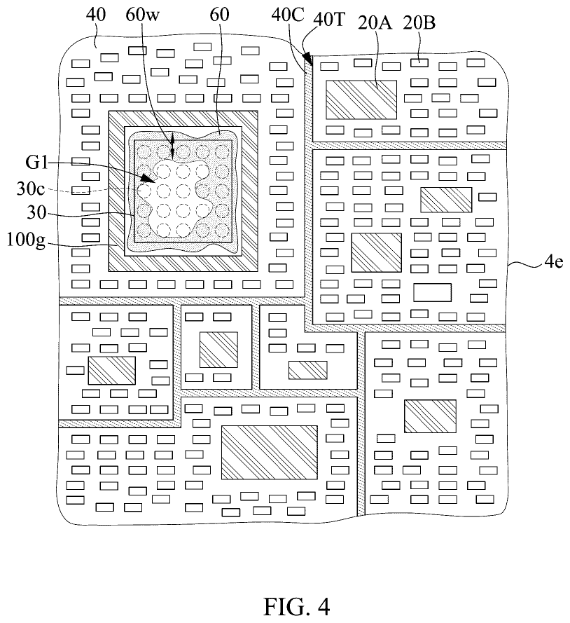

FIG. 4 is a top view of a package structure 4 in accordance with some arrangements of the present disclosure. The package structure 4 is similar to the package structure 1 in FIG. 1A and FIG. 1B, and the differences therebetween are described as follows.

In some arrangements, the barrier 60 has a non-uniform width 60w from a top view perspective. In some arrangements, the barrier 60 surrounds the connection elements 30c. In some arrangements, the gap G1 is surround and enclosed by the barrier 60. In some arrangements, the ground elements 100g extend at opposite sides of the barrier 60. In some arrangements, the package structure 4 has an irregularly shaped peripheral shape 4e from a top view perspective.

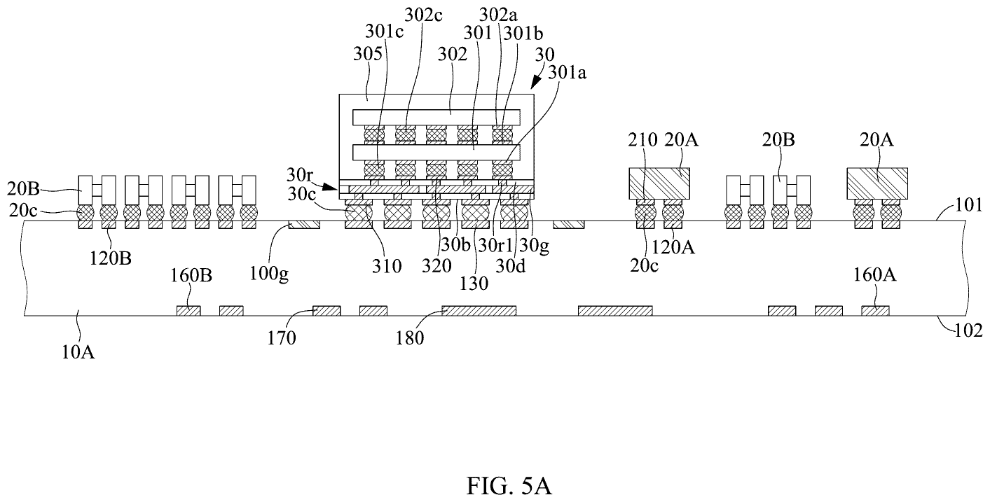

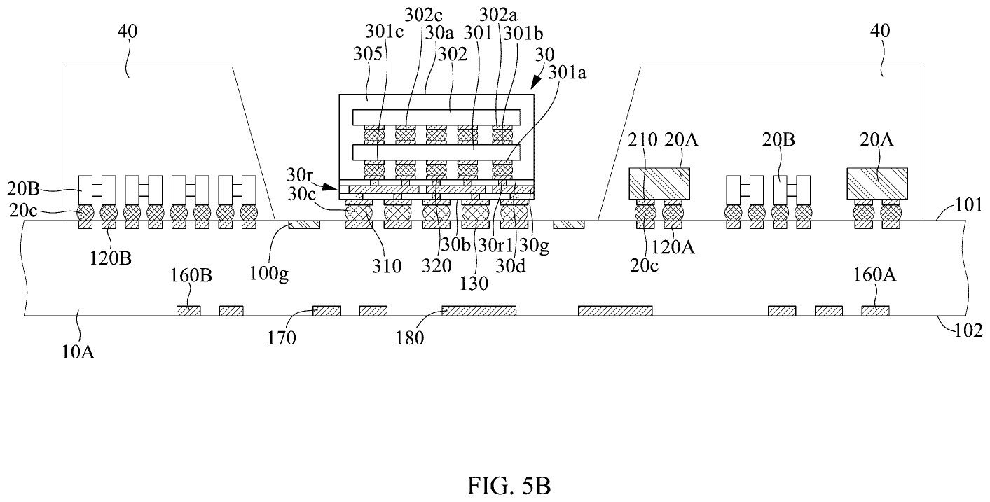

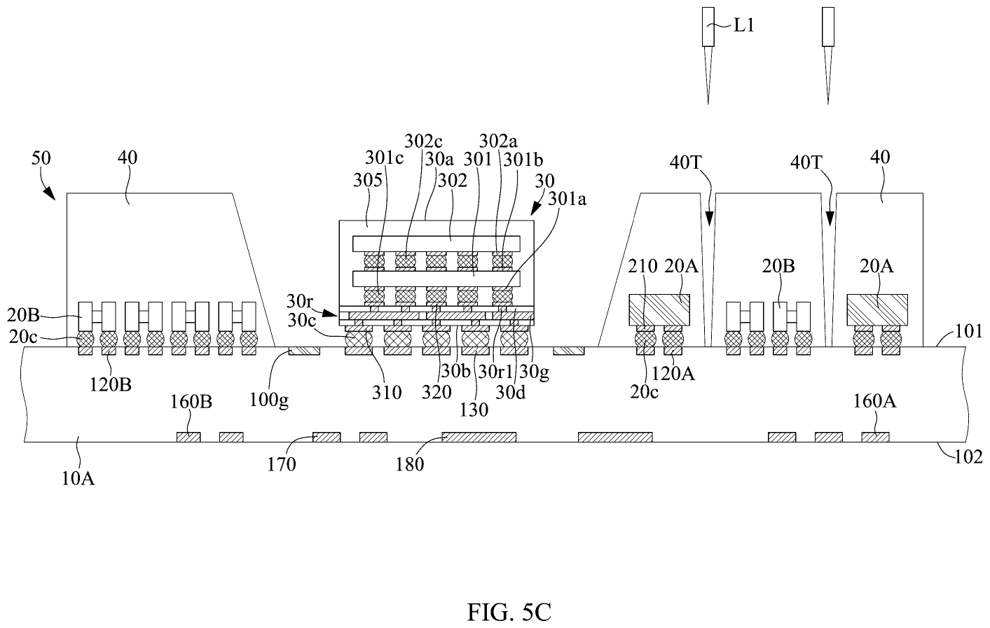

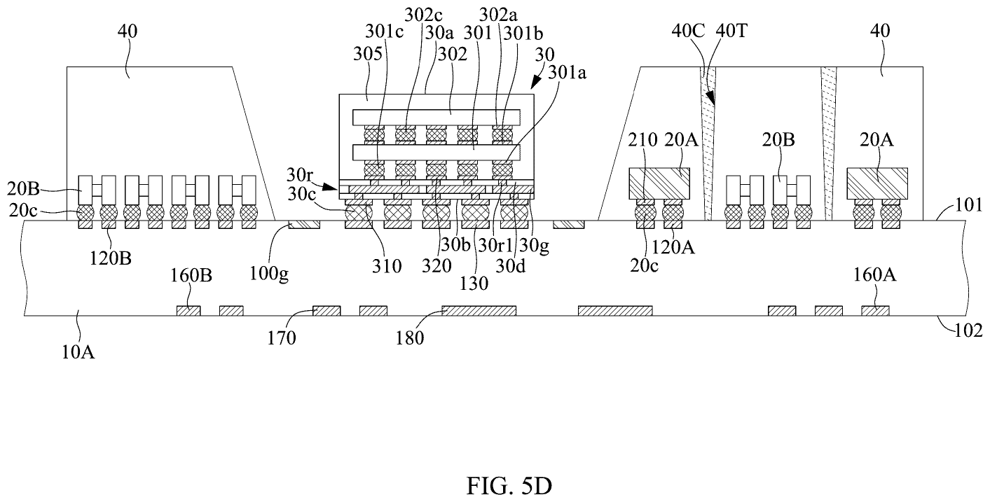

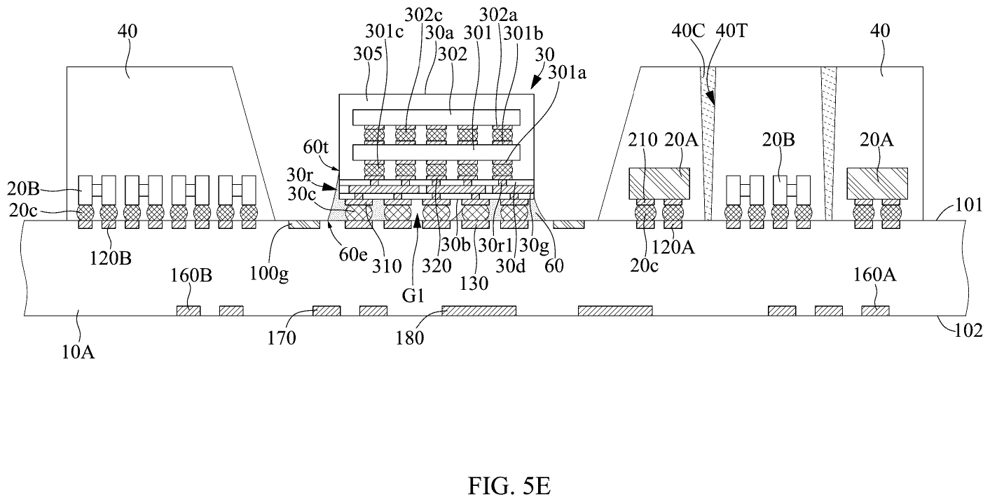

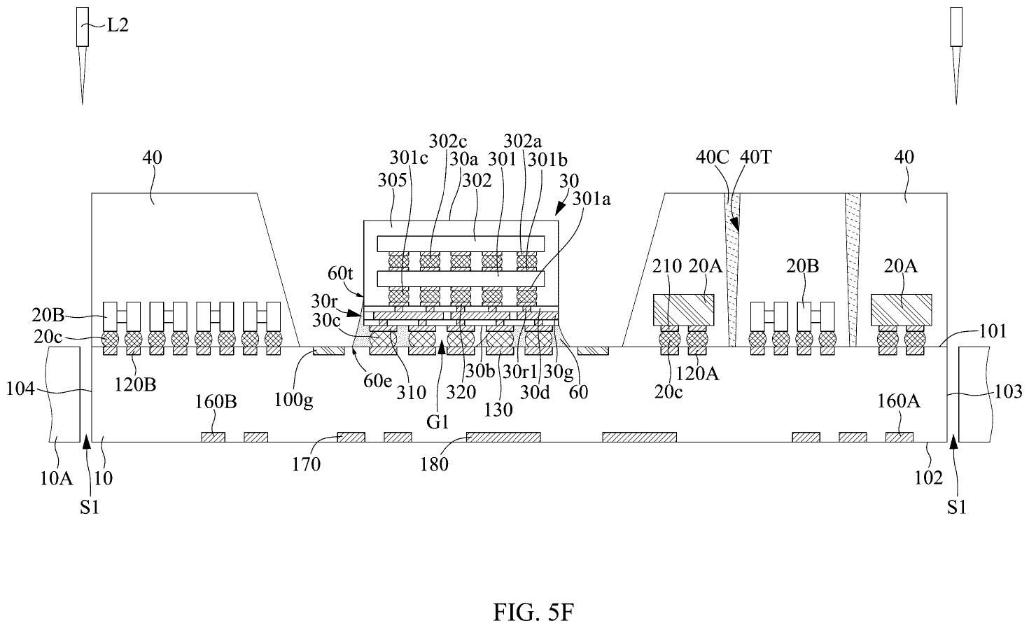

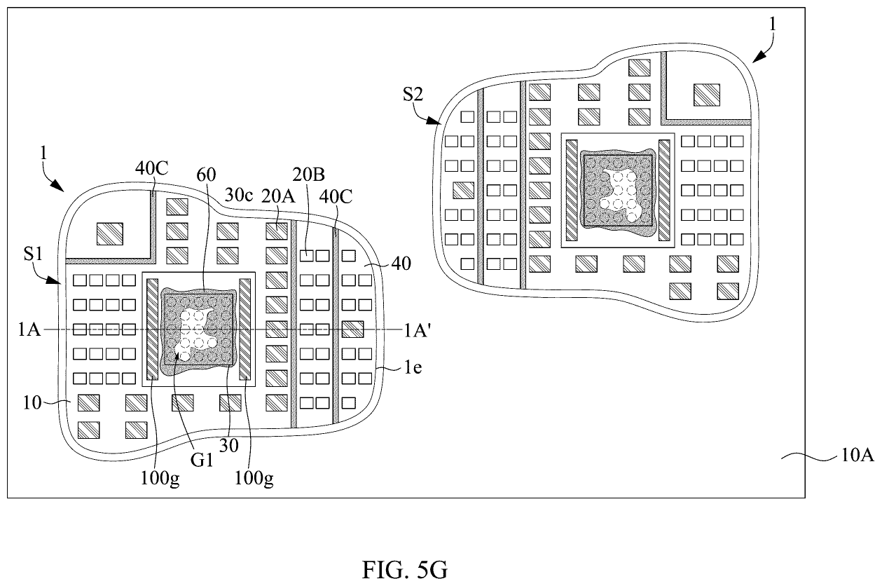

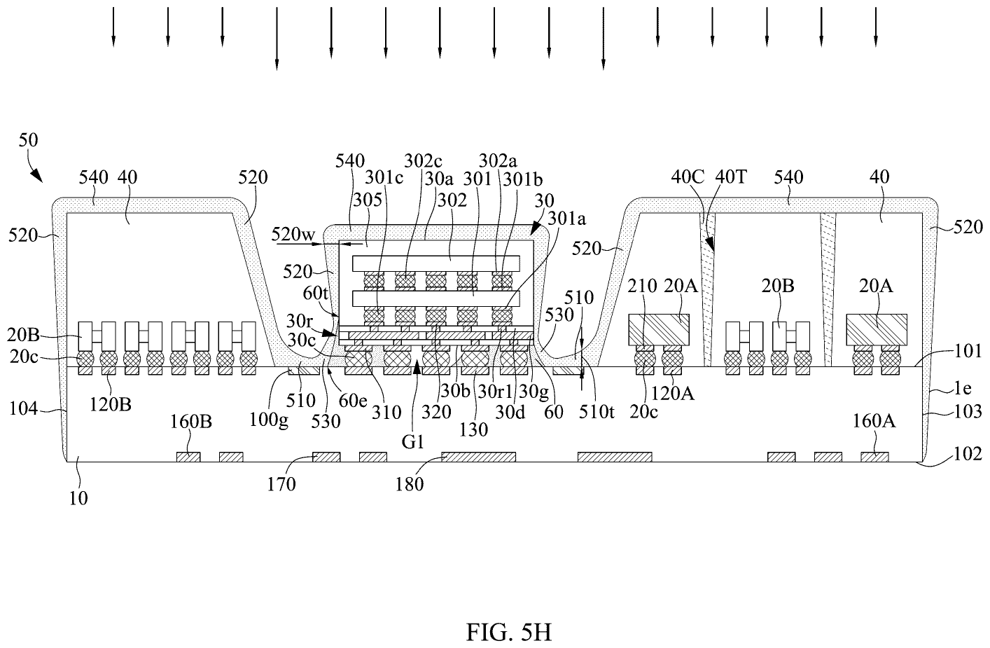

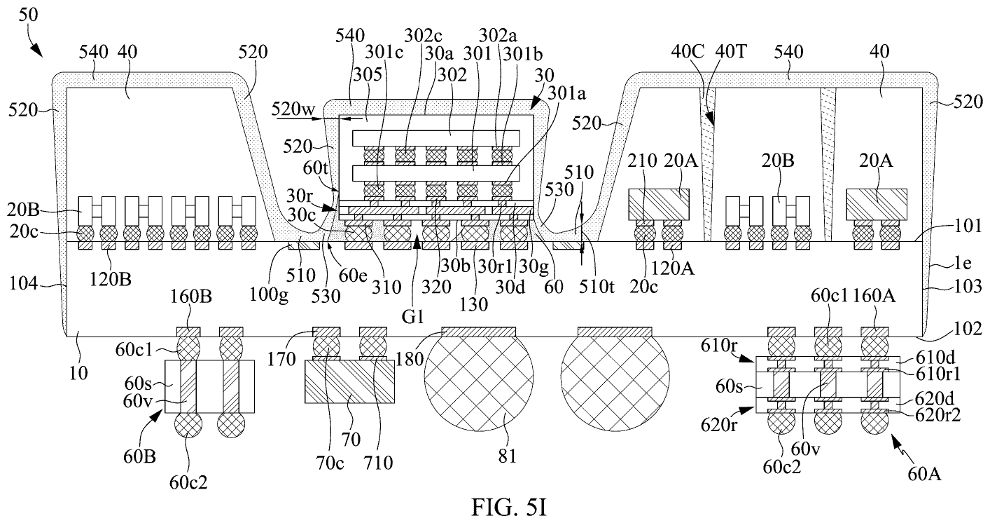

FIG. 5A to FIG. 5I illustrate various stages of an exemplary method of forming a package structure 1 in accordance with some arrangements of the present disclosure.

Referring to FIG. 5A, a substrate layer 10A may be provided, and electronic components 20A, 20B, and 30 may be disposed on or connected to the substrate layer 10A. In some arrangements, the substrate layer 10A is or includes a wafer-level substrate structure. The electronic components 20A, 20B, and 30 may be bonded to the substrate layer 10A through connection elements 20c and 30c (e.g., solder elements). In some arrangements, the electronic component 30 includes electronic devices 301 and 302 bonded to a RDL 30r through connection elements 301c and 302c (e.g., solder elements) by a reflow operation (e.g., a first reflow operation). In some arrangements, electronic components 20A, 20B, and 30 are bonded to the substrate layer 10A through connection elements the 20c and 30c (e.g., the solder elements) by a same reflow operation (e.g., a second reflow operation). In some arrangements, the substrate layer 10A has a surface 101 and a surface 102 opposite to the surface 101. In some arrangements, the substrate layer 10A includes conductive pads 120A, 120B, and 130 and a ground element 100g exposed from the surface 101. In some arrangements, the substrate 10 includes conductive pads 160A, 160B, 170, and 180 exposed from the surface 102.

Referring to FIG. 5B, an encapsulant 40 may be disposed over portions of the surface 101 of the substrate layer 10A to encapsulate the electronic components 20A and 20B and expose the electronic component 30. In some arrangements, the encapsulant 40 may be referred to as a selective mold.

Referring to FIG. 5C, trenches 40T may be formed in the encapsulant 40. In some arrangements, the trenches 40T penetrate the encapsulant 40. In some arrangements, portions of the encapsulant 40 are removed by applying heat energy through a laser using a laser equipment L1. In some arrangements, portions of the surface 101 are exposed to the trenches 40T.

Referring to FIG. 5D, conductive materials may be formed or filled in the trenches 40T to form shielding element 40C. In some arrangements, a conductive paste or a conductive glue is dispensed into the trenches 40T to form the shielding element 40C. In some arrangements, a metal material may be disposed or deposited in the trenches 40T to form the shielding element 40C.

Referring to FIG. 5E, a barrier 60 may be disposed around the connection elements 30c. In some arrangements, a barrier material may be disposed or dispensed around the connection elements 30c. The barrier material may be or include an insulating material, e.g., an underfill material. In some arrangements, the amount of the barrier material is sufficient to cover the outermost connection elements 30c to provide barrier functions, yet the amount of the barrier material cannot be too much to extend over the ground element 100g or even the encapsulant 40. As a result, due to the delicate control of the dispensing amount of the barrier material, the as-formed barrier 60 is formed to partially cover the lateral surfaces of the encapsulant layer 305 and partially cover the connection elements 30c, and a gap G1 is formed between the electronic component 30 and the substrate 10. In some arrangements, some of the connection elements 30c are exposed to or disposed in the gap G1.

Referring to FIG. 5F and FIG. 5G, FIG. 5G shows a top view of the stage illustrated in FIG. 5F. A singulation operation may be performed to form a plurality of package structures 1. In some arrangements, the singulation operation includes separating the substrate layer 10A into a plurality of substrates 10 with the electronic components 20A, 20B, and 30 connected thereto. In some arrangements, a laser equipment L2 may be used to separate the package structures 1 by scanning a laser beam along at least one or more separating line (e.g., lines S1 and S2). The separating lines may be referred to as scribing lines or cutting lines. Gaps may be formed along the lines S1 and S2. In some arrangements, the laser equipment L2 allows the laser beam to scan along the irregular shaped separating lines S1 and S2 to form package structures 1 having peripheral edges 1e with irregular shapes from a top view perspective.

Referring to FIG. 5H, a shielding material may be formed over the electronic component 30, the encapsulant 40, and the exposed surface 101 of the substrate 10 to form a shielding element 50. In some arrangements, the shielding element 50 is formed conformally over the substrate 10, the electronic component 30, and the encapsulant 40. In some arrangements, the shielding material may be formed by sputtering. In some arrangements, the shielding material may be formed by physical vapor deposition (PVD). In some arrangements, the shielding material may be supplied from above the electronic component 30, the encapsulant 40, and the exposed surface 101 of the substrate 10 and arriving the surfaces of the electronic component 30 and the encapsulant 40 and the exposed surface 101 of the substrate 10 in a direction from the encapsulant 40 toward the substrate 10.

Referring to FIG. 5I, connectors 60A and 60B, an electronic component 70, and electrical contacts 81 may be connected to the surface 102 of the substrate 10. The connectors 60A and 60B and the electronic component 70, may be bonded to the substrate 10 through connection elements 60c1 (e.g., solder elements) by a same reflow operation (e.g., a third reflow operation). As such, the package structure 1 illustrated in FIG. 1A and FIG. 1B may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a substrate;
a first electronic component and a second electronic component disposed over the substrate;
an encapsulant encapsulating the first electronic component and the second electronic component; and
a third electronic component exposed by the encapsulant, wherein a wafer node of the third electronic component is less than a wafer node of the first electronic component.

2. The package structure as claimed in claim 1, wherein the first electronic component comprises an active device, and the second electronic component comprises a passive device.

3. The package structure as claimed in claim 2, wherein the third electronic component comprises a first electronic device, a second electronic device, and an encapsulation layer encapsulating the first electronic device and the second electronic device, the encapsulation layer is spaced apart from the substrate, and a wafer node of at least one of the first electronic device and the second electronic device is less than the wafer node of the first electronic component.

4. The package structure as claimed in claim 3, further comprising:
a connection element electrically connecting the third electronic component to the substrate; and
a shielding layer disposed along an outer lateral surface of the encapsulant and an outer lateral surface of the third electronic component, wherein the shielding layer is free from contacting the connection element.

5. The package structure as claimed in claim 4, wherein the shielding layer is free from extending into a gap between the third electronic component and the substrate in a direction substantially perpendicular to a surface of the substrate.

6. The package structure as claimed in claim 4, further comprising a barrier disposed over the substrate and configured to space the shielding layer apart from the connection element.

7. The package structure as claimed in claim 6, wherein the barrier comprises at least a portion overlapping the third electronic component in a direction substantially parallel to a surface of the substrate, and the portion is configured to support the shielding layer.

8. The package structure as claimed in claim 7, wherein the shielding layer comprises a portion adhered to a lateral surface of the third electronic component and tapering toward the substrate.

9. The package structure as claimed in claim 6, wherein the barrier defines a space exposing a portion of a bottom surface of the third electronic component.

10. A package structure, comprising:
a substrate comprising a ground element at an upper surface of the substrate;
an encapsulant disposed on the upper surface of the substrate and exposing the ground element;
an electronic component disposed on the upper surface of the substrate exposed by the encapsulant, wherein the ground element is between the encapsulant and the electronic component;
a connection element disposed in a gap between the electronic component and the substrate and configured to electrically connecting the electronic component to the substrate; and
a dielectric layer encapsulating the connection element and spaced apart from the ground element, wherein the gap is not entirely filled by the dielectric layer.

11. The package structure as claimed in claim 10, wherein a lateral edge the dielectric layer is closer to the electronic component than to the encapsulant.

12. The package structure as claimed in claim 11, further comprising a shielding element between the ground element and the dielectric layer.

13. The package structure as claimed in claim 12, wherein the dielectric layer has a surface non-parallel to the upper surface of the substrate and configured to support the shielding element.

14. The package structure as claimed in claim 11, wherein the dielectric layer has a non-uniform width from a top view perspective.

15. A package structure, comprising:
a substrate;
a plurality of first electronic components over the substrate;
a first encapsulant encapsulating the first electronic components;
a plurality of second electronic components over the substrate and exposed by the first encapsulant; and
a first shielding layer adhered to an outer lateral surface of the first encapsulant and configured to accommodate the second electronic components.

16. The package structure as claimed in claim 15, wherein a gate length of one of the second electronic components is less than a gate length of one of the first electronic components.

17. The package structure as claimed in claim 15, further comprising a second encapsulant encapsulating the second electronic components, wherein the first shielding layer is between the first encapsulant and the second encapsulant.

18. The package structure as claimed in claim 17, further comprising a second shielding layer between the first electronic components and the second electronic components.

19. The package structure as claimed in claim 18, wherein a portion of the first encapsulant extends between the first shielding layer and the second shielding layer.

20. The package structure as claimed in claim 15, further comprising a first connection element electrically connected to one of the first electronic components and a second connection element electrically connected to one of the second electronic components, wherein a first intermetallic compound (IMC) layer between the first connection element and the one of the first electronic components has a first thickness, and a second IMC layer between the second connection element and the one of the second electronic components and has a second thickness substantially the same as the first thickness.
